(19) United States
(12) Patent Application Publication
(10) Pub. No.: US 2004/0104479 A1
(43) Pub. Date: Jun. 3, 2004

(54) Metal coated member and fabrication method thereof

(75) Inventors: Hideo Daimon, Tsukuba-gun (JP); Kohei Ugawa, Makabe-gun (JP); Nobuhiro Umebayashi, Tsukuba-shi (JP); Akito Sakemoto, Tsukuba-gun (JP)

Correspondence Address: OLIFF & BERRIDGE, PLC, P.O. BOX 19928, ALEXANDRIA, VA, 22320, US

(73) Assignee: HITACHI MAXELL, LTD., Ibaraki-shi (JP)

(21) Appl. No.: 10/679,874

(22) Filed: Oct. 7, 2003

(30) Foreign Application Priority Data
Oct. 11, 2002 (JP) 2002-298974
Nov. 7, 2002 (JP) 2002-324400
Feb. 25, 2003 (JP) 2003-047837
Feb. 25, 2003 (JP) 2003-047839

(51) Int. Cl. H01L 21/44; H01L 23/48

(52) U.S. Cl. 257/753; 257/766; 438/118

(57) ABSTRACT

A member having a metal layer is disclosed. The member is a silicon substrate or quartz substrate, for example, which is mainly composed of silicon or silicon oxide. A plurality of overhanging depressions are created on the surface of the member, and an anchor layer is formed thereon by filling the depressions. On the anchor layer is formed a metal film. The depressions are created by physical grinding followed by chemical etching. The anchor layer is NiP or NiB, for example. The metal layer is Au or AuSn, for instance.

### CROSS-REFERENCE TO RELATED APPLICATION

The present invention is related to Japanese Patent Application Serial No. 2002-298974, 2002-324400, 2003-47837, and 2003-47839. They are hereby incorporated.

### BACKGROUND OF THE INVENTION

1. Field of the Invention

The present invention relates to a member having a metal layer which is mainly composed of silicon or silicon oxide, and, more particularly, to a member having a metal layer which can be strongly soldered to another member.

2. Description of the Related Art

Optical fibers have almost identical composition to quartz; therefore, use of quartz optical communication components has received attention. For example, a lens for optical communication may be made of quartz instead of glass. An optical communication module in which a quartz optical communication component is mounted on a silicon substrate (silicon optical bench) mainly composed of silicon (Si) is a central part to optical communication. Such a module is required to have high reliability as a basic module in optical communication. Quartz substrates are also widely used, as well as silicon substrates, in the area of optical communication. They are used as substrates for optical wiring, gratings, variable dispersion compensators, and so on.

Conventionally, optical communication modules are fabricated by mounting a component on a silicon bench and then attaching them together with ultraviolet curable resin. This method is described in Japanese Unexamined Patent Application Publication No. S61-93419, for example. The modules fabricated in this method have no significant problem under normal temperature and humidity. However, the problem occurs under high temperature and humidity that the component comes off or is even detached from the silicon bench. A solution to this problem is to employ metal bonding instead of the UV curable resin bonding. The metal bonding includes soldering and welding. Soldering attachment requires formation of a metal layer on the portions being attached. A method for depositing a metal layer includes physical vapor deposition process such as vacuum evaporation and sputtering, and wet process such as electroless plating. The wet process by electroless plating is by far advantageous in terms of mass production.

Among conventional electroless plating processes is the one described in Japanese Unexamined Patent Application Publication No. H11-203674. It discloses the technique that electrolessly plates NiP on a glass substrate for a magnetic storage media. The technique provides the grass substrate with small depressions to improve adhesion strength of a plating layer to the substrate.

The above technique, however, is unable to provide a metal layer having enough adhesion strength for an optical communication component which is required to have very high durability. In the process of soldering or welding, a metal layer melts, causing detachment of the layer. This is called dissolution of metallization. To prevent the dissolution of metallization, the metal layer should have very strong adhesion and sufficient thickness.

### SUMMARY OF THE INVENTION

Accordingly, an object of the present invention is to provide a member with a metal layer having high durability and a fabrication method of the same. Another object of the present invention is to provide a member with a metal layer capable of strong metal bonding to another member.

A member having a metal layer according to the present invention is mainly composed of one of silicon and silicon oxide. The member has a plurality of overhanging depressions created on a surface of the member, an anchor layer formed by filling the depressions, and a metal layer formed on the anchor layer. The member with a metal layer having this structure shows strong adhesion when attached to another member by metal bonding,

It is preferred that a depth of the depressions is 1 μm to 4 μm. Further, the number of the depressions is preferably 1 to 4 per linear 15 μm on the surface of the member.

The anchor layer is preferably composed of Ni and at least one of P and B. The metal layer desirably contains Au. Further, it is preferred that a thickness of the anchor layer is 1 μm to 10 μm. The layer is preferably not more than 10 μm thick because an effect reaches saturation at this point and formation of a thicker layer is uneconomical.

In addition, a thickness of the metal layer is preferably 50 nm to 1 μm. The upper limit of the preferred range of the layer thickness is 1 μm because an effect reaches saturation at this point and formation of a thicker layer is uneconomical. The member having a metal layer is a quartz ferrule in one preferred embodiment.

In a preferred embodiment, the member having a metal layer described above is attached to another member by metal bonding.

A method of fabricating a member having a metal layer according to the present invention includes a step of creating a plurality of overhanging depressions on a surface of a member mainly composed of one of silicon and silicon oxide, a step of forming an anchor layer on the surface having the depressions by filling the depressions, and a step of forming a metal layer above the surface of the member with the anchor layer interposed therebetween. Preferably, the step of creating a plurality of overhanging depressions includes, in this order, a step of physically grinding the surface of the member, and a step of chemically etching the surface of the member.

Further, it is preferred that the step of chemical etching uses an etchant containing oxidizer. In one preferred embodiment, the step of forming an anchor layer and the step of forming a metal layer employ electroless plating.

Furthermore, it is desirable that the member is composed of silicon, and the above method further includes a step of oxidizing the surface of the member between the step of creating depressions and the step of forming an anchor layer.

A method of plating on a surface of a member according to the present invention includes, in this order, a step of creating a plurality of overhanging depressions on a surface of a member mainly composed of one of silicon and silicon oxide, and a step of forming a plating layer above the surface of the member.

An advantage of the present invention is to provide a member with a metal layer having high durability and a fabrication method of the same. More specifically, this invention can create depressions with overhanging sidewalls whose depth is 1 to 4 μm on a surface of a quartz base by way of chemically etching the base surface using an etchant containing a mixture of hydrogen peroxide with hydrofluoric acid, ammonium fluoride, or ammonium hydrogen fluoride after physical grinding. On the quartz base surface are thereby successively formed a NiP or NiB layer with a thickness of 1 μm or above, and an Au or AuSn layer with a thickness of 50 nm or above, and a quartz component can be attached to the base metallized by soldering. This allows significant increase in adhesion strength between the quartz component and the base.

The above and other objects, features and advantages of the present invention will become more fully understood from the detailed description given hereinbelow and the accompanying drawings which are given by way of illustration only, and thus are not to be considered as limiting the present invention.

### BRIF DESCRIPTION OF THE DRAWINGS

FIG. 1 is a cross sectional FIB-SIM image of the vicinity of a surface layer of a quartz component metallized with NiP/Au in an embodiment of the present invention.

FIG. 2 is a cross-sectional FIB-SIM image of the vicinity of a surface layer of a quartz component in a comparative example of the present invention.

### DECRIPTION OF THE PREFERRED EMBODIMENTS

A member having a metal layer according to the present invention is a member mainly composed of silicon or silicon oxide, including a quartz ferrule, silicon substrate, silicon optical bench, glass, quartz substrate, and quartz optical communication component. The member having a metal layer according to this invention is provided with a metal layer for attachment to another member by metal bonding. Another member to be attached to this member is also provided with a metal layer. In a preferred embodiment, a quartz ferrule is attached to a V-groove and the like on a silicon bench. The V-groove is a groove formed on a silicon substrate by anisotropic etching, including a trapezoidal groove with a flat bottom. When attaching the ferrule to the V-groove on the silicon bench by metal bonding, it is necessary to form a metal layer on the V-groove of the silicon bench and the outer side surface of the ferrule.

The attachment by metal bonding means attachment by soldering, welding, and so on, for example. Soldering is more advantageous in that attachment can be done with a simple device.

In the case of soldering attachment, the metal layer is preferably made of metal having good solder wettability. An example of such metal is a material mainly composed of Au, Sn, or an alloy of Au and Sn. The thickness of the metal layer is preferably from 50 nm to 1 μm. The layer thickness of 50 nm or more provides sufficient solder wettability, which is suitable for use for metal bonding. The upper limit of the preferred range of the layer thickness is 1 um because the effect reaches saturation at this point and formation of a thicker layer is uneconomical. The metal layer may be formed by electroless plating, for example.

Adhesion strength of a metal layer to a quartz ferrule, silicon substrate, silicon bench, glass, quartz optical communication component, and so on is extremely low. Therefore, the present invention deposits a metal layer on those members with an underlayer or an anchor layer interposed therebetween. The anchor layer is formed by electroless plating, for example. A layer having relatively high adhesion strength to silicon, glass, quartz and the like is preferred for use as the anchor layer. For example, the anchor layer is preferably formed by a material including Ni element and at least one of P and B elements, that is, a material including NiP and NiB. P concentration in NiP is preferably 2 to 15 at. %, and B concentration in NiB is preferably 1 to 10 at. %. In electroless nickel plating using phoshinic acid as reducing agent, concentration of P is desirably 2 to 15 at. %. In electroless nickel plating using dimethylamine-borane as reducing agent, concentration of B is desirably 1 to 10 at. %.

Further, the inventors of this invention have examined the surface treatment for silicon, glass, quartz, and so on. As a result, they have decided to create a plurality of small overhanging depressions on the surface of silicon, glass, and quartz. The overhanging depression has a shape that part or all of an inner side wall thereof protrudes inward in the vicinity of the surface where the depression is formed. Without the overhanging depressions, an anchor layer of more than 0.5 μm in thickness strips off the surface by stress of anchor layer. By way of creating the overhanging depressions and forming the anchor layer by filling the depressions, sufficient adhesion strength and thickness for preventing the dissolution of metallization have been achieved. The anchor layer is preferably 1 to 10 μm thick. The layer is preferably not more than 10 μm thick because the effect reaches saturation at this point and formation of a thicker layer is uneconomical.

The effect is achieved probably because a peculiar shape of the overhanging depressions on the surface of silicon and so on has a strong anchor effect. Further, even when high-temperature solder melts the anchor layer in the process of soldering, it is unable to melt the anchor layer stuck inside the overhanging depressions, which avoids the dissolution of metallization.

The depth of the depression is preferably 1 to 4 μm. The depth refers to the distance from the surface to the deepest point of the depression. The number of the depressions is preferably 1 to 4 per linear 15 μm on the surface of quartz and so on. No sufficient adhesion strength is obtained with less than one depression, and the effect is saturated with more than four depressions. The above range of the depth and number of depressions provide strong adhesion. The preferred depth of the depression is 4 μm or less in consideration of the surface roughness of a metal layer to be formed above the anchor layer.

In the following, a method of surface treatment to create multiple small overhanging depressions on the surfaces of silicon, glass, quartz, and the like will be explained with an example of a silicon substrate.

First, a silicon substrate surface is physically ground to create a rough surface. The physical grinding process preferably uses sandblasting or grinding with abrasive grains of #300 to #1000. Next, the surface is further roughed by chemical etching. In the chemical etching, the silicon substrate is soaked in an etchant containing a mixture of hydrogen peroxide with hydrofluoric acid, ammonium fluoride, or ammonium hydrogen fluoride. This process creates a plurality of small overhanging depressions. Similar surface treatment for glass or quartz results in the same effect.

The use of oxidizer such as hydrogen peroxide as a chemical etchant enables to create overhanging depressions having sufficient width. This allows formation of an anchor layer inside the depressions. Specifically, the use of oxidizer for a chemical etchant oxidizes the silicon substrate surface and forms on the silicon substrate an oxide layer of silicon having a plurality of small overhanging depressions.

The formation of the silicon oxide layer is advantageous when forming an anchor layer by electroless plating. This is because metal catalyst such as Pd, which should be attached to a surface in electroless plating, is more strongly attached to silicon oxide such as quartz than to silicon.

In addition, it is preferred to further provide an oxidation process since the oxide layer formed in the chemical etching process may be thin. The oxidation process, for example, places the silicon substrate in steam of 1000 to 1100° C. The oxide layer is preferably 1 to 2 μm thick.

Providing the oxidation process after the surface treatment process ensures formation of a silicon oxide layer having multiple small overhanging depressions on the silicon substrate.

The oxidation process is necessary when forming a metal layer on a silicon bench, silicon substrate, and the like. The process is unnecessary when forming a metal layer on an optical communication component made of quartz which is an oxide of silicon.

Various components may be mounted on a silicon substrate, silicon optical bench, quartz substrate, and so on. When an active element such as a laser diode is mounted thereon, heating is a problem since prolonged use may causes errors due to heat. The metal layer may serve as a heat-releasing layer to release heat from the silicon substrate, silicon optical bench, quartz substrate, and the like. This allows stable operation of optical communication components such as a laser diode, maintaining high durability. Further, the metal layer may also serve as a conductive path for electrical signal output by a photoelectric transfer element.

In the case where the metal layer in this invention is used as the heat-releasing layer, the layer is preferably made of material mainly composed of metal having high electric or thermal conductivity. The metal with high electric or thermal conductivity is preferably Cu, Ni, or Cr. When used as the heat-releasing layer, the preferred thickness of the metal layer is 300 μm and above, which is thicker than the preferred thickness (50 nm to 1 μm) of the same when used for a metal bonding.

Since a high level of durability is required for optical communication components, the metal layer used as the heat-releasing layer should also be strongly adhered to a quartz substrate. Therefore, the present invention creates a plurality of small overhanging depressions on the quartz substrate surface, forms an anchor layer thereon to fill the depressions, and then deposits a metal layer on the anchor layer.

The process of forming a metal layer used as a heat-releasing layer on a quartz substrate is as follows. First, a similar treatment to the above-described surface treatment for the silicon substrate is provided on the surface of a quartz substrate. Multiple small overhanging depressions are thereby created on the quartz substrate surface. Next, an anchor layer is formed by electroless plating. Optimal values of the depth of the depressions and the thickness of the anchor layer are the same as those described above. Then, a metal layer made of material mainly composed of Cu, Ni, or Cr is formed by electroplating. A module including the quartz substrate fabricated in this process has strong adhesion of the metal layer, thus being capable of long and stable operation.

The process of forming a metal layer used as a heat-releasing layer on a silicon substrate, on the other hand, is as follows. First, the above surface treatment for the silicon substrate is provided to form a silicon oxide layer having multiple small overhanging depressions. Next, an anchor layer is formed by electroless plating. Optimal values of the depth of the depressions and the thickness of the anchor layer are the same as those described above. Then, a metal layer made of material mainly composed of Cu, Ni, or Cr is formed by electroplating. A module including the silicon substrate fabricated in this process has strong adhesion of the metal layer, thereby being capable of long and stable operation.

### EXAMPLE 1

The surface of a twin-core cylindrical quartz ferrule with an outside diameter of 2 mm and length of 7 mm was physically ground with abrasive grains of #800. Then, the ferrule was soaked for 10 minutes in an etchant containing ammonium hydrogen fluoride of 4 wt. % and hydrogen peroxide of 11 wt. % at normal temperature. After washed, the ferrule was soaked for 2 minutes in a 10N sodium hydroxide solution at normal temperature. The ferrule was then washed and soaked for 3 minutes in a 75 g/L solution of cationic surfactant OPC-370M by Okuno Chemical Industries Co. Ltd. at normal temperature. Further, after washed, the ferrule was soaked for 3 minutes in a hydrochloric acid solution of one-component catalyst 9F by Shipley Far East Ltd. at normal temperature. After washed, the ferrule was soaked for 3 minutes in a sulfuric acid solution of Accelerator 240 by Shipley Far East Ltd. at normal temperature. Then, after washed, the ferrule was soaked for 10 minutes in an electroless Ni plating solution NP-700 by Nisshin-Kasei Corporation at a bath temperature of 85° C. Finally, after washed, the ferrule was soaked for 5 minutes in a displacement electroless Au plating solution Muden Noble AU by Okuno Chemical Industries Co. Ltd. at a bath temperature of 65° C. A member (ferrule) with a metal layer in this invention was thereby completed.

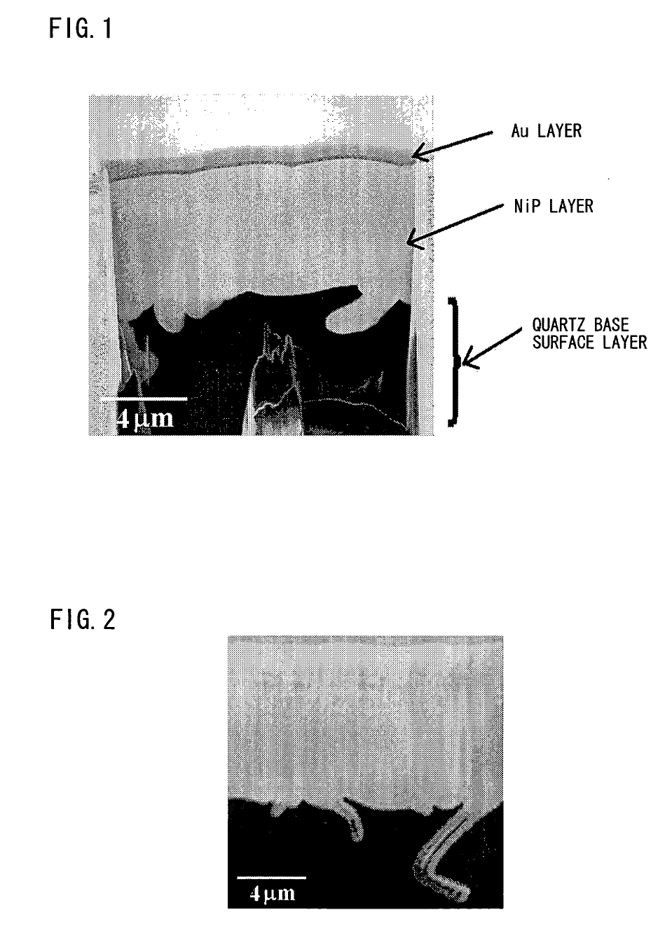

FIG. 1 is a cross sectional SIM image of the vicinity of a surface layer of the ferrule metallized with NiP/Au. As shown therein, the height of the overhangs created on the ferrule surface was 2 to 3 μm, and the thickness of the NiP layer was 6 to 8 μm. P concentration in NiP was 3 at. %. The thickness of the Au layer above the NiP layer was 100 nm. A peel test was conducted on the ferrule metallized with NiP/Au using Scotch Mending Tape #810, which resulted in no layer peeling occurred.

Similarly, Ti, Pt, and Au layers were formed by sputtering on a surface of a V-groove on a silicon optical bench (which will be referred to hereinafter as a Si-OB).

Then, the ferrule was attached to the Si-OB by soldering. The dissolution of metallization did not occur. Measurement of soldering strength showed adhesion strength of 2 kg and above. The Si-OB with the ferrule attached thereto by soldering was placed for 2000 hours in the environment of 85° C. and 90% relative humidity. Further, a heat cycle test for 500 cycles between 85° C. and −40° C. was conducted thereon. The result was that the ferrule did not come off nor was detached from the Si-OB.

### EXAMPLE 2

The surface of a twin-core cylindrical quartz ferrule with an outside diameter of 2 mm and length of 7 mm was physically ground with abrasive grains of #800. Then, the ferrule was soaked for 10 minutes in an etchant containing ammonium hydrogen fluoride of 4 wt. % and hydrogen peroxide of 11 wt. % at normal temperature. After washed, the ferrule was soaked for 2 minutes in a 10N sodium hydroxide solution at normal temperature. The ferrule was then washed and soaked for 3 minutes in a 75 g/L solution of cationic surfactant OPC-370M by Okuno Chemical Industries Co. Ltd. at normal temperature. Further, after washed, the ferrule was soaked for 3 minutes in a hydrochloric acid solution of one-component catalyst 9F by Shipley Far East Ltd. at normal temperature. After washed, the ferrule was soaked for 3 minutes in a sulfuric acid solution of Accelerator 240 by Shipley Far East Ltd. at normal temperature. The ferrule was again washed and soaked for 10 minutes in an electroless NiB plating solution Kaniboron by Japan Kanigen Co. Ltd. at a bath temperature of 85° C. Finally, after washed, the ferrule was soaked for 5 minutes in a displacement electroless Au plating solution Muden Noble AU by Okuno Chemical Industries Co. Ltd. at a bath temperature of 65° C. A member (ferrule) with a soldered metal layer in this invention was thereby completed. Cross-sectional SIM observation of the vicinity of the ferrule surface layer showed that the height of the overhangs created on the ferrule surface was 2 to 3 μm, and the thickness of the NiB layer was 6 to 8 μm.

B concentration in NiB was 2 at. %. The thickness of the Au layer above the NiB layer was 100 nm. A peel test was conducted on the ferrule metallized with NiB/Au using Scotch Mending Tape #810, which resulted in no layer peel-off occurred.

Next, Ti, Pt, and Au layers are formed on the surface of a Si-OB by sputtering.

Then, the ferrule was attached to the Si-OB by soldering. The dissolution of metallization did not occur. Measurement of soldering strength showed adhesion strength of 2 kg and above. Then, the Si-OB with the ferrule attached thereto by soldering was placed for 2000 hours in the environment of 85° C. and 90% relative humidity. Further, a heat cycle test for 500 cycles between 85° C. and −40° C. was conducted thereon. The result was that the ferrule did not come off nor was detached from the SI-OB.

### EXAMPLE 3

A silicon (100) substrate of 1.5 mm in thickness was anisotropically etched to create a trapezoidal V-goove of 1000 μm in width, 500 μm in depth, and 5 mm in length, thereby fabricating a silicon optical bench. Then, a surface of the silicon bench opposite to the surface with the V-groove was plated in the following process.

1. Surface Treatment Process

An object was ground with abrasive grains of #800. Then, the object was soaked for 10 minutes in an etchant containing ammonium hydrogen fluoride of 4 wt. % and hydrogen peroxide of 11 wt. % at normal temperature.

2. Oxide Layer Formation Process

The object was placed in steam of 1000° C. for 5 hours to form an oxide layer on the surface. The thickness of the oxide layer was approximately 1.2 μm.

3. Pretreatment Process for Plating

The object was soaked for 2 minutes in a 10N sodium hydroxide solution at normal temperature. After washed, the object was soaked for 3 minutes in a 75 g/L solution of cationic surfactant OPC-370M by Okuno Chemical Industries Co. Ltd. at normal temperature.

4. Metal Catalyst Coating Process

After washed, the object was soaked for 3 minutes in a hydrochloric acid solution of one-component catalyst 9F by Shipley Far East Ltd. at normal temperature. Then, the object was washed and further soaked for 3 minutes in a sulfuric acid solution of Accelerator 240 by Shipley Far East Ltd. at normal temperature.

5. Anchor Layer Plating Process

After washed, the object was soaked for 10 minutes in an electroless Ni plating solution NP-700 by Nisshin-Kasei Corporation at a bath temperature of 85° C. An anchor layer composed of nickel phosphide was thereby formed.

6. Metal Layer Plating Process

After washed, the object was soaked for 10 minutes in a displacement electroless Au plating solution Muden Noble AU by Okuno Chemical Industries Co. Ltd. at a bath temperature of 65° C. A metal layer (Au layer) was thus formed, creating a finished object.

The cross-sectional SIM image of the vicinity of the metal layer surface on the finished object was observed. On the surface of the object was formed a silicon oxide layer with multiple small overhanging depressions. The depressions were 2 to 3 μm in depth. The cross-sectional SIM image showed that approximately 3 depressions were created per linear 15 μm on the object surface. The thickness of the anchor layer was 6 to 8 μm, and P concentration in the anchor layer was 3 at. %. The thickness of the metal layer above the anchor layer was 100 nm. A peel test was conducted on the metal layer using Scotch Mending Tape #810, which resulted in no layer peeling occurred.

### EXAMPLE 4

The surface of a glass substrate was physically ground with abrasive grains of #800. Then, the glass substrate was soaked for 10 minutes in an etchant containing ammonium hydrogen fluoride of 4 wt. % and hydrogen peroxide of 11 wt. % at normal temperature. After washed, the glass substrate was soaked for 2 minutes in a 10N sodium hydroxide solution at normal temperature. The glass substrate was again washed and soaked for 3 minutes in a 75 g/L solution of cationic surfactant OPC-370M by Okuno Chemical Industries Co. Ltd. at normal temperature. Then, after washed, the glass substrate was soaked for 3 minutes in a hydrochloric acid solution of one-component catalyst 9F by Shipley Far East Ltd. at normal temperature. After washed, the glass substrate was soaked for 3 minutes in a sulfuric acid solution of Accelerator 240 by Shipley Far East Ltd. at normal temperature. Further, the glass substrate was washed and was soaked for 10 minutes in an electroless Ni plating solution NP-700 by Nisshin-Kasei Corporation at a bath temperature of 85° C. Finally, after washed, the glass substrate was soaked for 5 minutes in a displacement electroless Au plating solution Muden Noble AU by Okuno Chemical Industries Co. Ltd. at a bath temperature of 65° C. A grass substrate to accommodate soldering according to the present invention was thereby completed.

The height of the overhangs created on the glass substrate surface was 2 to 3 μm. The thickness of the NiP layer was 6 to 8 μm. P concentration in NiP was 3 at. %. The thickness of the Au layer above the NiP layer was 100 nm. A peel test was conducted on the ferrule metallized with NiP/Au using Scotch Mending Tape #810, which resulted in no layer peeling occurred.

### COMPARATIVE EXAMPLE 1

The surface of a twin-core cylindrical quartz ferrule with an outside diameter of 2 mm and length of 7 mm was soaked for 2 minutes in a 200 m/L hydrofluoric acid solution at normal temperature. After washed, the ferrule was soaked for 2 minutes in a 10N sodium hydroxide solution at normal temperature. The ferrule was then washed and further soaked for 3 minutes in a 75 g/L solution of cationic surfactant OPC-370M by Okuno Chemical Industries Co. Ltd. at normal temperature. After washed, the ferrule was soaked for 3 minutes in a hydrochloric acid solution of one-component catalyst 9F by Shipley Far East Ltd. at normal temperature. The ferrule was again washed and soaked for 3 minutes in a sulfuric acid solution of Accelerator 240 by Shipley Far East Ltd. at normal temperature. Then, after washed, the ferrule was soaked for 10 minutes in an electroless Ni plating solution NP-700 by Nisshin-Kasei Corporation at a bath temperature of 85° C. Further, the ferrule was washed and again soaked for 5 minutes in a displacement electroless Au plating solution Muden Noble AU by Okuno Chemical Industries Co. Ltd. at a bath temperature of 65° C. A ferrule with a metal layer metallized with NiP/Au was thereby completed. A peel test was conducted on the ferrule using Scotch Mending Tape #810. The result was that layer peel-off occurred at the interface between the ferrule and the NiP. Cross-sectional SIM observation of the vicinity of the surface layer of the ferrule showed that no overhanging depression was created on the ferrule surface. It was also shown that the ferrule surface had a peak to valley roughness of 0.5 μm, the NiP layer had a thickness of 6 to 8 μm, and the Au layer above the NiP layer had a thickness of 100 nm. P concentration in NiP was 3 at. %.

Next, Ti, Pt, and Au layers were formed on a surface of a Si-OB by sputtering.

Then, the ferrule with a metal layer was attached to the Si-OB by soldering. Measurement of soldering strength showed adhesion strength of 0.4 kg. The Si-OB with the ferrule attached thereto by soldering was placed for 2000 hours in the environment of 85° C. and 90% relative humidity. Further, a heat cycle test for 500 cycles between 85° C. and −40° C. was conducted thereon. The test result was that the ferrule came off the Si-OB.

### COMPARATIVE EXAMPLE 2

The surface of a twin-core cylindrical quartz ferrule was physically ground with abrasive grains of #800. Then, the ferrule was soaked for 10 minutes in an etchant containing ammonium hydrogen fluoride of 4 wt. % at normal temperature. The etchant does not contain hydrogen peroxide. After washed, the ferrule was soaked for 2 minutes in a 10N sodium hydroxide solution at normal temperature. The ferrule was then washed and soaked for 3 minutes in a 75 g/L solution of cationic surfactant OPC-370M by Okuno Chemical Industries Co. Ltd. at normal temperature. Further, after washed, the ferrule was soaked for 3 minutes in a hydrochloric acid solution of one-component catalyst 9F by Shipley Far East Ltd. at normal temperature. The ferrule was again washed and soaked for 3 minutes in a sulfuric acid solution of Accelerator 240 by Shipley Far East Ltd. at normal temperature. Then, after washed, the ferrule was soaked for 10 minutes in an electroless Ni plating solution NP-700 by Nisshin-Kasei Corporation at a bath temperature of 85° C. Finally, after washed, the ferrule was soaked for 5 minutes in a displacement electroless Au plating solution Muden Noble AU by Okuno Chemical Industries Co. Ltd. at a bath temperature of 65° C. A ferrule with a metal layer was thereby completed.

The height of the overhangs created on the ferrule surface was 2 to 3 μm. The thickness of the NiP layer was 6 to 8 μm. P concentration in NiP was 3 at. %. The Au layer above the NiP layer was 100 nm thick. Since the width of the depressions was narrower than the above example, the NiP layer failed to fill the depressions. FIG. 2 shows a cross-sectional SIM image of the vicinity of the surface layer of the ferrule in this comparative example. A peel test was conducted on the ferrule metallized with NiP/Au using Scotch Mending Tape #810, which resulted in occurrence of layer peel-off.

### REFERENCE EXAMPLE

The surface of a twin-core cylindrical quartz ferrule with an outside diameter of 2 mm and length of 7 mm was physically ground with abrasive grains of #800. Then, the ferrule was soaked for 10 minutes in an etchant containing ammonium hydrogen fluoride of 4 wt. % and hydrogen peroxide of 11 wt. % at normal temperature. After washed, the ferrule was soaked for 2 minutes in a 10N sodium hydroxide solution at normal temperature. The ferrule was then washed and soaked for 3 minutes in a 75 g/L solution of cationic surfactant OPC-370M by Okuno Chemical Industries Co. Ltd. at normal temperature. Further, after washed, the ferrule was soaked for 3 minutes in a hydrochloric acid solution of one-component catalyst 9F by Shipley Far East Ltd. at normal temperature. After washed, the ferrule was soaked for 3 minutes in a sulfuric acid solution of Accelerator 240 by Shipley Far East Ltd. at normal temperature. The ferrule was again washed and soaked for 10 minutes in an electroless Ni plating solution NP-700 by Nisshin-Kasei Corporation at a bath temperature of 85° C. Finally, after washed, the ferrule was soaked for 5 minutes in a displacement electroless Au plating solution Muden Noble AU by Okuno Chemical Industries Co. Ltd. at a bath temperature of 65° C. A ferrule with a metal layer was thereby completed. Cross-sectional SIM observation of the vicinity of the ferrule surface layer metallized with NiP/Au showed that the height of the overhangs created on the ferrule surface was 2 to 3 μm, the thickness of the NiP layer was 6 to 8 μm, and the thickness of the Au layer above the NiP layer was 100 nm. P concentration in NiP was 3 at. %. A peel test was conducted on the ferrule metallized with NiP/Au using Scotch Mending Tape #810, which resulted in no layer peeling occurred. Next, the quartz ferrule was attached to a silicon substrate using ultraviolet curable resin. Adhesion strength was 0.7 kg. The ferrule attached to the silicon substrate with ultraviolet curable resin was then placed for 2000 hours in the environment of 85° C. and 90% relative humidity. Further, a heat cycle test for 500 cycles between 85° C. and −40° C. was conducted thereon. The test result was that the ferrule came off the silicon substrate.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A member having a metal layer, the member mainly composed of one of silicon and silicon oxide, comprising:
a plurality of overhanging depressions created on a surface of the member;
an anchor layer formed by filling the depressions; and
a metal layer formed on the anchor layer.

2. A member having a metal layer according to claim 1, wherein a depth of the depressions is 1 μm to 4 μm.

3. A member having a metal layer according to claim 1, wherein the number of the depressions is 1 to 4 per linear 15 μm on the surface of the member.

4. A member having a metal layer according to claim 1, wherein the anchor layer is composed of Ni and at least one of P and B.

5. A member having a metal layer according to claim 1, wherein the metal layer contains Au.

6. A member having a metal layer according to claim 1, wherein a thickness of the anchor layer is at least 1 μm.

7. A member having a metal layer according to claim 1, wherein a thickness of the metal layer is at least 50 nm.

8. A member having a metal layer according to claim 1, wherein the member is a quartz ferrule.

9. A module comprising a member having a metal layer according to claim 1, the member being attached to another member by metal bonding.

10. A member having a metal layer according to claim 1, wherein the member is composed of silicon and further comprises an oxide layer on a surface thereof.

11. A method of fabricating a member having a metal layer, comprising:
a step of creating a plurality of overhanging depressions on a surface of a member mainly composed of one of silicon and silicon oxide;
a step of forming an anchor layer on the surface having the depressions by filling the depressions; and
a step of forming a metal layer above the surface of the member with the anchor layer interposed therebetween.

12. A method of fabricating a member having a metal layer according to claim 11, the step of creating a plurality of overhanging depressions comprising:
a step of physically grinding the surface of the member; and
a step of chemically etching the surface of the member, the step being subsequent to the step of physical grinding.

13. A method of fabricating a member having a metal layer according to claim 12, wherein the step of chemical etching uses an etchant containing oxidizer.

14. A method of fabricating a member having a metal layer according to claim 11, wherein the step of forming an anchor layer and the step of forming a metal layer employ electroless plating.

15. A method of fabricating a member having a metal layer according to claim 11, wherein the member is composed of silicon, and the method further comprises a step of oxidizing the surface of the member between the step of creating depressions and the step of forming an anchor layer.

16. A method of plating on a surface of a member, comprising:
a step of creating a plurality of overhanging depressions on a surface of a member mainly composed of one of silicon and silicon oxide; and
a step of forming a plating layer above the surface of the member, the step being subsequent to the step of creating depressions.
